(19) United States
(12) Patent Application Publication
(10) Pub. No.: US 2016/0087764 A1
(43) Pub. Date: Mar. 24, 2016

(54) TRANSMITTER AND RECEIVER CIRCUIT, INTEGRATED CIRCUIT, AND TESTING METHOD

(71) Applicant: SOCIONEXT INC., Yokohama-shi (JP)

(72) Inventor: Naoto TSUCHIYA, Yokohama (JP)

(21) Appl. No.: 14/846,124

(22) Filed: Sep. 4, 2015

(30) Foreign Application Priority Data
Sep. 18, 2014 (JP) 2014-190471

(51) Int. Cl. H04L 1/20; H03K 5/135

(52) U.S. Cl. CPC H04L 1/205; H03K 5/135; H03K 2005/00052

(57) ABSTRACT

A transmitter and receiver circuit includes a phase interpolator that generates a process clock having a phase based on a reference clock, a first selector that selects a first clock so that the first clock is the process clock in a first mode and is the reference clock in a second mode, a deserializer that converts a serial input data into a parallel output data in accordance with the first clock and outputs the parallel output data, a second selector that selects a second clock so that the second clock is the reference clock in the first mode and is the process clock in the second mode, and a serializer that converts a second parallel input data into a serial output data according to the second clock and outputs the serial output data.

### CROSS-REFERENCE TO RELATED APPLICATIONS

This application is based upon and claims the benefit of priority of the prior Japanese Patent Application No. 2014-190471, filed on Sep. 18, 2014, the entire contents of which are incorporated herein by reference.

### FIELD

The embodiments discussed herein are related to a transmitter and receiver circuit, an integrated circuit, and a testing method.

### BACKGROUND

In a high-speed data transmission between transmitter and receiver circuits that are used in USB (Universal Serial Bus), SATA (Serial Advanced Technology Attachment), or the like, the receiver circuit restores from received data a clock that is used for judging a logic (that is, judging logic 0 or 1) of the received data. In order to correctly judge the logic of the received data, a phase of the clock that is restored in the receiver circuit is adjusted by a feedback circuit within the receiver circuit, so that a phase error between the clock and the received data becomes constant. A CDR (Clock and Data Recovery) refers to the recovery of the clock that is used for judging the logic of the received data in the receiver circuit, and the recovery of transmission data by judging the logic of the received data using the recovered clock.

The receiver circuit that receives serial data by the CDR requires correct reception of the serial data including a jitter to a certain extent. When inspecting a tolerable amount of jitter of the receiving apparatus by a loopback test, there are known techniques to generate serial data including a desired jitter, as proposed in Japanese Laid-Open Patent Publications No. 2006-303786, No. 2004-260677, and No. 2005-233933, for example.

However, according to the conventional techniques, a circuit exclusively for generating the serial data including the desired jitter needs to be newly prepared, and a configuration for inspecting the tolerable amount of jitter by the loopback test may easily become complex.

### SUMMARY

Accordingly, it is an object in one aspect of the embodiments to provide a transmitter and receiver circuit, an integrated circuit, and a testing method that can inspect a tolerable amount of jitter by a loopback test using a simple configuration.

According to one aspect of the embodiments, a transmitter and receiver circuit includes a phase interpolator configured to generate a process clock having a phase based on a reference clock; a first selector configured to select a first clock so that the first clock is the process clock in a first mode and is the reference clock in a second mode; a deserializer configured to convert a serial input data into a parallel output data in accordance with the first clock, and output the parallel output data; a second selector configured to select a second clock so that the second clock is the reference clock in the first mode and is the process clock in the second mode; and a serializer configured to convert a second parallel input data into a serial output data according to the second clock, and output the serial output data.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an example of a configuration of a transmitter and receiver circuit;

FIG. 2 is a diagram for explaining an example of a normal operation of the transmitter and receiver circuit;

FIG. 3 is a diagram for explaining an example of a test operation of the transmitter and receiver circuit;

FIG. 4 is a diagram illustrating an example of a test environment of the transmitter and receiver circuit; and

FIG. 5 is a flow chart for explaining an example of a testing method of the transmitter and receiver circuit.

### DESCRIPTION OF EMBODIMENTS

Preferred embodiments of the present invention will be described with reference to the accompanying drawings.

A description will now be given of the transmitter and receiver circuit, the integrated circuit, and the testing method in each embodiment according to the present invention.

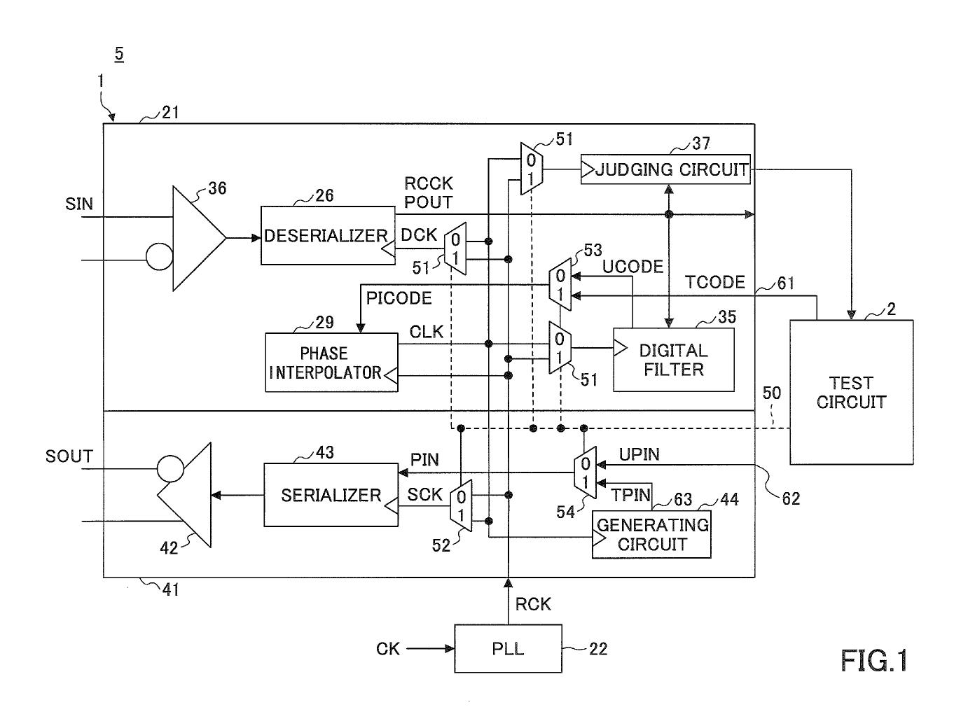

FIG. 1 is a diagram illustrating an example of a configuration of an integrated circuit 5 including a transmitter and receiver circuit 1 in one embodiment. In this example, the integrated circuit 5 is a serializer and deserializer (SerDes) that converts serial data into parallel data and vice versa. For example, the integrated circuit 5 is a semiconductor chip including a PLL (Phase Locked Loop) 22, the transmitter and receiver circuit 1, and a test circuit 2. For example, the transmitter and receiver circuit 1 is a communication circuit including a transmitter circuit 41 and a receiver circuit 21.

The PLL 22 is a clock generating circuit that generates a reference clock RCK based on a source clock CK. The PLL 22 outputs the reference clock RCK to each of the transmitter circuit 41 and the receiver circuit 21 of the transmitter and receiver circuit 1.

The test circuit 2 outputs to the transmitter and receiver circuit 1 a switching signal 50 for selectively switching an operation mode of the transmitter and receiver circuit 1 to one of a normal mode (or first mode) and a test mode (or second mode).

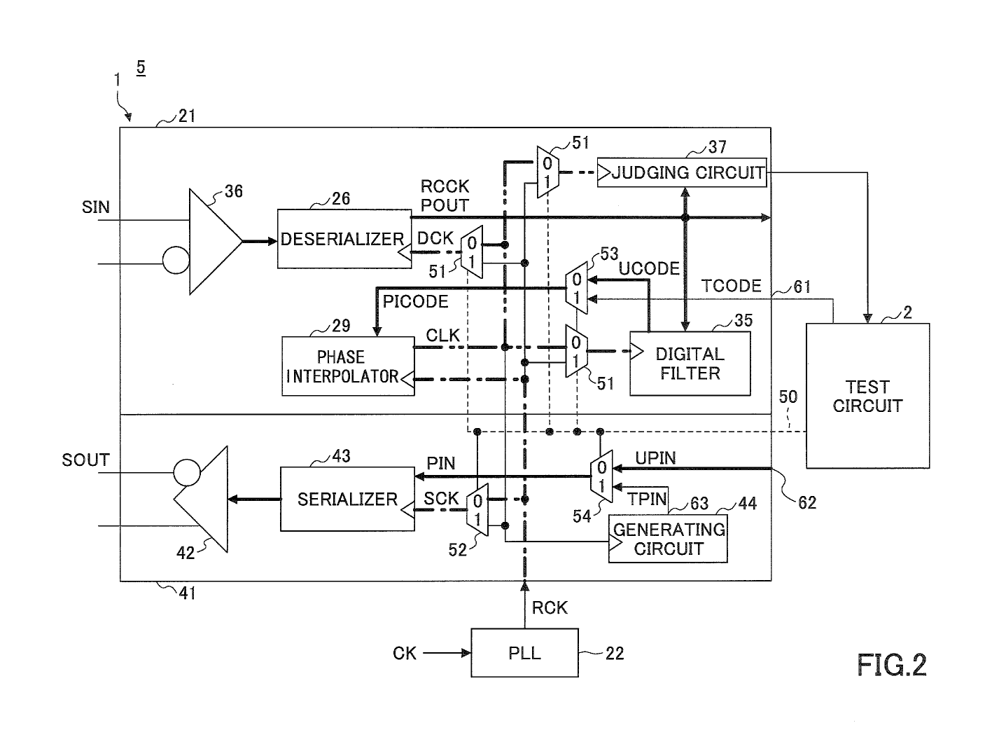

FIG. 2 is a diagram for explaining an example of a normal operation of the transmitter and receiver circuit 1 in the normal mode. FIG. 2 illustrates an example of a flow of signals within the transmitter and receiver circuit 1 in the normal mode. The normal mode is an operation mode in which the transmitter circuit 41 converts a parallel pattern UPIN into a serial output data SOUT according to the reference clock RCK to output the serial output data SOUT, and the receiver circuit 21 converts a serial input data SIN into parallel output data POUT according to a process clock CLK to output the parallel output data POUT. The process clock CLK is generated by a PI (Phase Interpolator) 29 based on the reference clock RCK. In the normal mode, the transmitter circuit 41 transmits the serial output data SOUT to a receiver circuit (not illustrated) different from the receiver circuit 21, and the receiver circuit 21 receives the serial input data SIN from a transmitter circuit (not illustrated) different from the transmitter circuit 41.

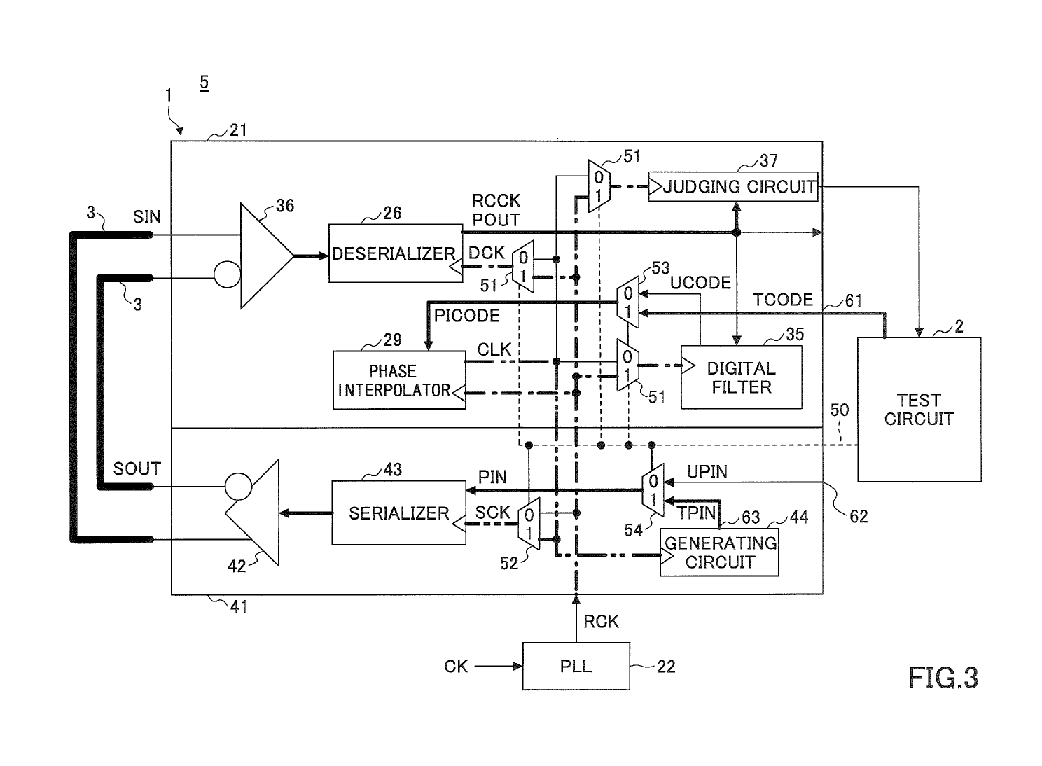

FIG. 3 is a diagram for explaining an example of a test operation of the transmitter and receiver circuit 1 in a test mode. FIG. 3 illustrates an example of the flow of the signals within the transmitter and receiver circuit 1 in the test mode. The test mode is an operation mode in which an output of the transmitter circuit 41 and an input of the receiver circuit 21 are connected via a loopback line (or wiring) 3 when performing a loopback test that inspects the transmitter and receiver circuit 1. By connecting the output of the transmitter circuit 41 and the input of the receiver circuit 21, the serial output data SOUT output from the transmitter circuit 41 is input, as the serial input data SIN, to the receiver circuit 21.

For example, the receiver circuit 21 includes a PI (Phase Interpolator) 29, a selector 51, and a deserializer 26. The PI 29 is a circuit that generates the process clock CLK having a desired phase according to the reference clock RCK. The selector 51 is a selection circuit that selectively switches a first input clock DCK that is input to the deserializer 26, according to the switching signal 50. The selector 51 is an example of a first selector to select the process clock CLK as the input clock DCK that is input to the deserializer 26 in the normal mode illustrated in FIG. 2, and to select the reference clock RCK as the input clock DCK that is input to the deserializer 26 in the test mode illustrated in FIG. 3. The deserializer 26 is a circuit that converts the serial input data SIN into the parallel output data POUT, according to the input clock DCK that is selected by the selector 51, and outputs the parallel output data POUT.

In other words, the deserializer 26 in the normal mode can convert the serial input data SIN into the parallel output data POUT according to the process clock CLK, to output the parallel output data POUT. In addition, the deserializer 26 in the test mode can convert the serial input data SIN into the parallel output data POUT according to the reference clock RCK, to output the parallel output data POUT.

For example, the transmitter circuit 41 includes a selector 52 and a serializer 43. The selector 52 is a selection circuit that selectively switches a second input clock SCK that is input to the serializer 43, according to the switching signal 50. The selector 52 is an example of a second selector to select the reference clock RCK as the input clock SCK that is input to the serializer 43 in the normal mode illustrated in FIG. 2, and to select the process clock CLK as the input clock SCK that is input to the serializer 43 in the test mode illustrated in FIG. 3. The serializer 43 is a circuit that converts the parallel input data PIN into the serial output data SOUT, according to the input clock SCK that is selected by the selector 52, and outputs the serial output data SOUT.

In other words, the serializer 43 in the normal mode can convert the parallel input data PIN into the serial output data SOUT according to the reference clock RCK, to output the serial output data SOUT. In addition, the serializer 43 in the test mode can convert the parallel input data PIN into the serial output data SOUT according to the process clock CLK that is generated by the PI 29, to output the serial output data SOUT.

Accordingly, the serial output data SOUT including a desired amount of jitter can be generated by utilizing a phase adjusting function of the PI 29, without having to prepare a circuit exclusively for generating the serial output data SOUT including the desired amount of jitter. For example, the PI 29 can vary (that is, increase or decrease) an amount of change in the phase of the process clock CLK, so as to generate the desired amount of jitter in the process clock CLK. Hence, the serializer 43 can convert the parallel input data PIN into the serial output data SOUT according to the process clock CLK that includes the predetermined amount of jitter, in order to generate the serial output data SOUT that includes the desired amount of jitter.

In addition, the deserializer 26 in the test mode converts the serial input data SIN into the parallel output data POUT according to the reference clock RCK, to output the parallel output data POUT. Because the transmitter circuit 41 and the receiver circuit 21 are connected via the loopback line 3, the serial output data SOUT including the desired amount of jitter is input, as the serial input data SIN, to the deserializer 26. Hence, the deserializer 26 can convert the serial input data SIN including the desired amount of jitter into the parallel output data POUT, according to the reference clock RCK, and output the parallel output data POUT. Therefore, by judging true or false (or correct or error state) of the parallel output data POUT that is output from the deserializer 26, it is possible to inspect the tolerable amount of jitter of the receiver circuit 21 using a simple configuration.

Next, a more detailed description will be given of an example of the configuration of the transmitter and receiver circuit 1.

The receiver circuit 21 is a deserializer circuit that converts the serial input data SIN into the parallel output data POUT according to the reference clock RCK, and outputs the parallel output data POUT together with a recovered clock RCCK. For example, the receiver circuit 21 includes a differential receiver 36, the deserializer 26, a digital filter 35, an adjusting node 61, a selector 53, the PI 29, and a judging circuit 37.

The differential receiver 36 is a circuit that converts the serial input data SIN that is input to the receiver circuit 21 from a differential signal into a single-end signal. In a case in which the serial input data SIN that is input to the receiver circuit 12 is the single-end signal, the differential receiver 36 may be omitted.

The deserializer 26 converts the serial input data SIN into the parallel output data POUT according to the input clock DCK, to output the parallel output data POUT. The deserializer 26 latches by a latch circuit thereof the serial input data SIN at a timing corresponding to a rising edge or a falling edge of the input clock DCK. The deserializer 26 deserializes a serial output data DT of the latch circuit into the parallel output data POUT amounting to a predetermined number of rows (for example, 16 rows), according to the recovery clock RCCK that is obtained by frequency-dividing the input clock DCK by a frequency divider. In addition, the deserializer 26 detects a boundary of the serial input data SIN, and outputs a boundary detection data BT.

The digital filter 35 in the normal mode detects a phase error between the process clock CLK and the serial input data SIN, based on the parallel output data POUT. For example, the digital filter 35 compares the parallel output data POUT that is output from the deserializer 26 and the boundary detection data BT, and generates a phase information code PDCCODE that indicates whether the phase of the process clock CLK is advanced or lagging compared to the phase of the serial input data SIN, according to the recovered clock RCCK. For example, the digital filter 35 includes a PDC (Phase to Digital Converter) that outputs a digitization (−1, 0, +1) indicating whether a timing (or sampling timing of the serial input data SIN) corresponding to the rising edge of the process clock CLK is advanced or lagging with respect to a predetermined ideal timing.

For example, in a case in which the phase of the process clock CLK is detected as being advanced compared to the phase of the serial input data SIN, the digital filter 35 outputs the phase information code PDCCODE that is “−1” to indicate the need to delay the phase of the process clock CLK. In addition, in a case in which the phase of the process clock CLK is detected as lagging compared to the phase of the serial input data SIN, the digital filter 35 outputs the phase information code PDCCODE that is “+1” to indicate the need to advance the phase of the process clock CLK. Further, in a case in which the phase of the process clock CLK is detected as being the same as the phase of the serial input data SIN, the digital filter 35 outputs the phase information code PDCCODE that is “0” to indicate no need to adjust the phase of the process clock CLK.

The digital filter 35 outputs a phase adjusting code (an example of a phase adjusting signal) UCODE that instructs a phase adjusting amount (or phase shift amount) required to shift the phase of the process clock CLK by an amount corresponding to 1 bit of the serial input data SIN, and outputs the phase adjusting code UCODE according to an accumulated result of the phase error that is detected in the manner described above. For example, the digital filter 35 subjects the phase information code PDCCODE to a superposition integral and a time-average, and outputs the phase adjusting code UCODE that instructs an amount of phase shift (or phase adjusting amount) of the process clock CLK.

The digital filter 35 operates according to the clock that is selected by the selector 51 in the normal mode. For example, the digital filter 35 outputs the phase adjusting code UCODE according to the process clock CLK that is selected by the selector 51 in the normal mode. On the other hand, the digital filter 35 operates according to the reference clock RCK that is selected by the selector 51 in the test mode. However, since the phase adjusting code UCODE is unnecessary for the test mode, the digital filter 35 does not need to operate in the test mode.

The adjusting node 61 is a node to which a test adjusting code (an example of a test adjusting signal) TCODE that is used in the test mode is input, and is connected to the test circuit 2 that generates the test adjusting code TCODE. The test adjusting code TCODE is a test signal for instructing a phase adjusting amount that is required to vary the phase of the process clock CLK by the desired amount of jitter.

The selector 53 is a selecting circuit that selectively switches an adjusting code PICODE input to the PI 29, according to the switching signal 50. The selector 53 is an example of a third selector to select the phase adjusting code UCODE as the adjusting code PICODE that is input to the PI 29 in the normal mode illustrated in FIG. 2, and to select the test adjusting code TCODE as the adjusting code PICODE that is input to the PI 29 in the test mode illustrated in FIG. 3.

The PI 29 shifts the phase of the process clock CLK according to the adjusting code PICODE that is selected by the selector 53. The PI 29 outputs the process clock CLK that is obtained by shifting the phase of the reference clock RCK according to the adjusting code PICODE.

In other words, the PI 29 in the normal mode can shift the phase of the process clock CLK according to the phase adjusting code UCODE. In addition, the PI 29 in the test mode can generate the process clock CLK that includes the desired jitter, by varying the phase of the process clock CLK according to the test adjusting code TCODE.

Accordingly, the receiver circuit 21 that operates in the normal mode can adjust the phase of the process clock CLK by a CDR loop that includes the PI 29, according to the amount of jitter included in the serial input data SIN, so that the rising edge of the process clock CLK is positioned in a vicinity of a center of an eye pattern of the serial input data SIN. The process clock CLK is recovered as a clock for judging the logic of the serial input data SIN, and the transmission data is recovered using the recovered process clock CLK.

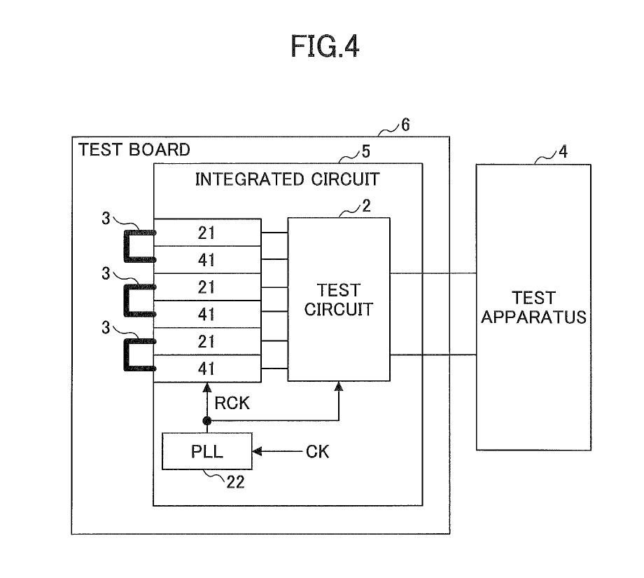

The judging circuit 37 is a testing circuit that judges true or false (or correct or error state) of the parallel output data POUT in the test mode. For example, the judging circuit 37 compares a test pattern TPIN that is input to the serializer 43 and the parallel output data POUT that is recovered by the deserializer 26. Details of the test pattern TPIN will be described later. In a case in which the test pattern TPIN and the parallel output data POUT match, the judging circuit 37 judges that the parallel output data POUT is true (that is, correct or normal). On the other hand, in a case in which the test pattern TPIN and the parallel output data POUT do not match, the judging circuit 37 judges that the parallel output data POUT is false (that is, error or abnormal). The judging circuit 37 outputs a judgment result on the true or false of the parallel output data POUT with respect to the test circuit 2. The test circuit 2 outputs a judgment signal in accordance with the judgment result with respect to a test apparatus 4 that is connected to the test circuit 2. The test apparatus 4 will be described in more detail in conjunction with FIG. 4. For example, the test apparatus 4 displays whether the parallel output data POUT is true or false (that is, normal or abnormal), according to the judgment signal.

The judging circuit 37 operates according to the clock that is selected by the selector 51 in the test mode. For example, the judging circuit 37 judges the true or false of the parallel output data POUT, according to the reference clock RCK that is selected by the selector 51 in the test mode. On the other hand, the judging circuit 37 operates according to the process clock CLK that is selected by the selector 51 in the normal mode. However, since the true or false judgment of the parallel output data POUT is unnecessary for the normal mode, the judging circuit 37 does not need to operate in the normal mode.

On the other hand, the transmitter circuit 41 is a serializer circuit that converts the parallel pattern UPIN input in the normal mode into the serial output data SOUT, according to the reference clock RCK, to output the serial output data SOUT. For example, the transmitter circuit 41 includes a normal input node 62, a test input node 63, a generating circuit 44, a selector 54, the selector 52, the serializer 43, and a differential driver 42.

The normal input node 62 is a node to which the parallel pattern UPIN used in the normal mode is input. The normal input node 62 is connected to a preceding-stage circuit (not illustrated) that outputs the parallel pattern UPIN. The parallel pattern UPIN is parallel data amounting to a predetermined number of rows.

The test input node 63 is a node to which the test pattern TPIN used in the test mode is input. The test input node 63 is connected to the generating circuit 44 that generates the test pattern TPIN. The test pattern TPIN is a parallel data that is input to the serializer 43 in order to inspect the tolerable amount of jitter of the receiver circuit 21. The generating circuit 44 operates according to the process clock CLK.

The selector 54 is a selecting circuit that selectively switches the parallel input data PIN input to the serializer 43. The selector 54 is an example of a fourth selector that selects the parallel pattern UPIN as the parallel input data PIN in the normal mode illustrated in FIG. 2, and selects the test pattern TPIN as the parallel input data PIN in the test mode illustrated in FIG. 3.

The serializer 43 converts the parallel input data PIN selected by the selector 54 into the serial output data SOUT, according to the input clock SCK selected by the selector 52, to output the serial output data SOUT.

In other words, the serializer 43 in the normal mode can convert the parallel pattern UPIN into the serial output data SOUT according to the reference clock RCK. In addition, the serializer 43 in the test mode can convert the test pattern TPIN into the serial output data SOUT according to the process clock CLK.

The differential driver 42 is a circuit that converts the serial output data SOUT output from the serializer 43 from the single-end signal into the differential signal, to output the differential signal. In a case in which the serial output data SOUT output from the transmitter circuit 41 is a single-end signal, the differential driver 42 may be omitted.

In the case of this embodiment, the jitter included in the serial output data SOUT may be represented by a sum St of “a jitter caused by characteristics of the transmitter circuit 41”, “a jitter caused by characteristics of the PLL 2”, “a jitter caused by characteristics of the PI 29”, and a jitter caused by the test adjusting code TCODE″, for example. In other words, the frequency of the jitter and the amount of the jitter included in the serial output data SOUT can be adjusted by varying the test adjusting code TCODE to an arbitrary value.

On the other hand, in the case of this embodiment, the jitter included in the parallel output data POUT may be represented by a sum Sr of “a jitter caused by characteristics of the receiver circuit 21”, “a jitter caused by characteristics of the deserializer 26”, and “a jitter caused by characteristics of the PLL 22”.

Because the transmitter circuit 41 and the receiver circuit 21 are connected by the loopback line 3, the receiver circuit 21 can correctly receive the serial input data SIN including the jitter in a case in which a relationship St+Sr<1UI stands, where 1UI represents 1 period of the serial data. The judging circuit 37 judges that the parallel output data POUT is normal in a case in which the relationship St+Sr<1UI stands.

The “jitter caused by the characteristics of the transmitter circuit 41” is caused by a power supply voltage, a process, a temperature, a power supply noise, or the like of the transmitter circuit 41, for example. The “jitter caused by the characteristics of the PLL 22” is caused by the power supply voltage, the process, the temperature, the power supply noise, or the like of the PLL 22, for example. The “jitter caused by the characteristics of the PI 29” is caused by a phase adjusting accuracy, the power supply voltage, the process, the temperature, the power supply noise, or the like of the PI 29, the phase of the reference clock RCK, or the like, for example. The “jitter caused by the characteristics of the receiver circuit 21” is caused by the power supply voltage, the process, the temperature, the power supply noise, or the like of the receiver circuit 21, the data pattern, amplitude, or the like of the serial input data SIN, or the like, for example. The “jitter caused by the characteristics of the deserializer 26” is caused by the characteristics of a setup time or a hold time of the latch circuit at an initial stage of the deserializer 26, for example.

FIG. 4 is a diagram illustrating an example of a test environment of the transmitter and receiver circuit 1. The integrated circuit 5 includes a plurality of transmitter and receiver circuits 1 respectively having the transmitter circuit 41 and the receiver circuit 21, and the test circuit 2. Each of the plurality of transmitter and receiver circuits 1 are connected to the test circuit 2. By setting the integrated circuit 5 on a test board 6, the transmitter circuit 41 and the receiver circuit 21 of each transmitter and receiver circuit 1 are connected by the loopback line 3, and the test circuit 2 is connected to the test apparatus 4.

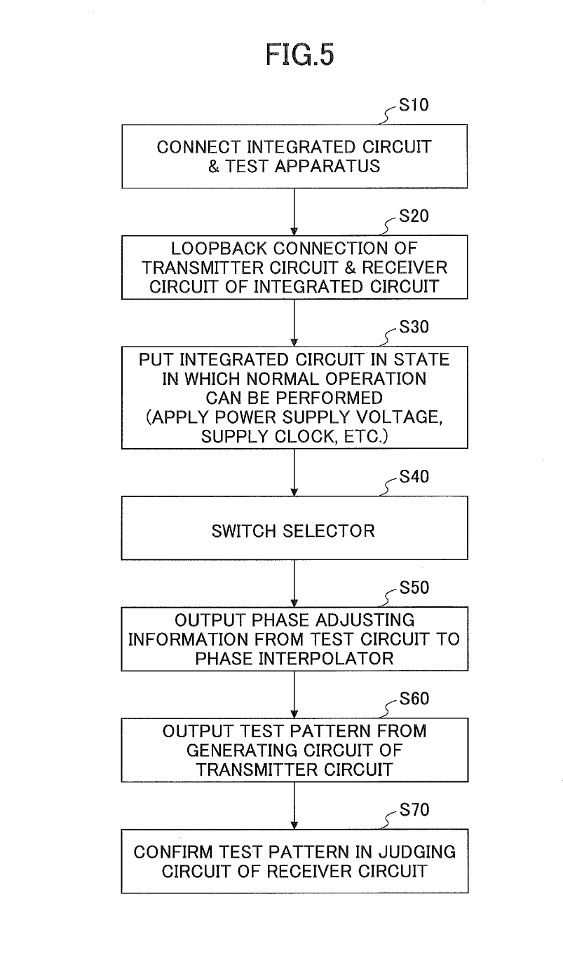

FIG. 5 is a flow chart for explaining an example of a testing method for inspecting the tolerable amount of jitter of the transmitter and receiver circuit 1.

In step S10 illustrated in FIG. 5, the integrated circuit 5 is connected to the test apparatus 4. The integrated circuit 5 is set on the test board 6 so that the test apparatus 4 is communicably connected to the test circuit 2 on the integrated circuit 5.

In step S20, the output of the serializer 43 of the transmitter circuit 41 and the input of the serializer 26 of the receiver circuit 21 are connected. The test apparatus 4 provides a loopback connection between the serializer 43 and the deserializer 26, by setting the integrated circuit 5 on the test board 6.

In step S30, the test apparatus 4 applies a power supply voltage to the integrated circuit 5 and supplies the source clock CK to the integrated circuit 5, in order to put the integrated circuit 5 into a state in which the normal operation can be performed.

In step S40, the reference clock RCK is selected as the input clock DCK that is input to the deserializer 26, and the process clock CLK is selected as the input clock SCK that is input to the serializer 43. The test apparatus 4 instructs the test circuit 2 so as to output the switching signal 50 for setting the operation mode of the transmitter and receiver circuit 1 to the test mode.

In step S50, the test adjusting code TCODE that instructs the phase shift amount for shifting the phase of the process clock CLK to the PI 29 is output. The test apparatus 4 instructs the test circuit 2 to output the test adjusting code TCODE that generates the desired amount of jitter in the process clock CLK.

In step S60, the test pattern TPIN that is input as the parallel input data PIN is output. The test apparatus 4 instructs the test circuit 2 to output the predetermined test pattern TPIN from the generating circuit 44.

In step S70, the true or false of the parallel output data POUT is judged. The test apparatus 4 displays whether the parallel output data POUT is normal or abnormal, according to the judgment signal that is output from the judging circuit 37.

According to the transmitter and receiver circuit, the integrated circuit, and the testing method of the embodiment, it is possible to inspect the tolerable amount of jitter by the loopback test using a simple configuration.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A transmitter and receiver circuit comprising:
a phase interpolator configured to generate a process clock having a phase based on a reference clock;
a first selector configured to select a first clock so that the first clock is the process clock in a first mode and is the reference clock in a second mode;
a deserializer configured to convert a serial input data into a parallel output data in accordance with the first clock, and output the parallel output data;
a second selector configured to select a second clock so that the second clock is the reference clock in the first mode and is the process clock in the second mode; and
a serializer configured to convert a second parallel input data into a serial output data according to the second clock, and output the serial output data.

2. The transmitter and receiver circuit as claimed in claim 1, further comprising:
a digital filter configured to accumulate a phase error between the serial input data and the process clock based on the parallel output data, and output a phase adjusting signal that instructs a phase shift amount for shifting the phase of the process clock in accordance with an accumulated result of the phase error;
an adjusting node configured to receive a test adjusting signal that is used in the second mode; and
a third selector configured to select a first adjusting signal that is the phase adjusting signal in the first mode and is the test adjusting signal in the second mode,
wherein the phase interpolator is configured to shift the phase of the process clock in accordance with the first adjusting signal.

3. The transmitter and receiver circuit as claimed in claim 2, wherein the digital filter is configured to operate in accordance with the first clock.

4. The transmitter and receiver circuit as claimed in claim 2, further comprising:
a first input node configured to receive a third parallel pattern that is used in the first mode;
a second input node configured to receive a test pattern that is used in the second mode; and
a fourth selector configured to select the parallel input data so that the parallel input data is the third parallel pattern in the first mode and is the test pattern in the second mode.

5. The transmitter and receiver circuit as claimed in claim 4, further comprising:
a generating circuit coupled to the second input node and configured to generate the test pattern.

6. The transmitter and receiver circuit as claimed in claim 1, further comprising:
a judging circuit configured to judge true or false of the parallel output data.

7. The transmitter and receiver circuit as claimed in claim 6, wherein the judging circuit is configured to operate in accordance with the first clock.

8. An integrated circuit comprising:
a clock generating circuit configured to generate a reference clock; and
a transmitter and receiver circuit including
a phase interpolator configured to generate a process clock having a phase based on the reference clock;
a first selector configured to select a first clock so that the first clock is the process clock in a first mode and is the reference clock in a second mode;
a deserializer configured to convert a serial input data into a parallel output data in accordance with to the first clock, and output the parallel output data;
a second selector configured to select a second clock so that the second clock is the reference clock in the first mode and is the process clock in the second mode; and
a serializer configured to convert a second parallel input data into a serial output data according to the second clock, and output the serial output data.

9. The integrated circuit as claimed in claim 8, further comprising:
a test circuit configured to switch an operation mode of the transmitter and receiver circuit between the first mode and the second mode.

10. The integrated circuit as claimed in claim 8, wherein the transmitter and receiver circuit further includes
a digital filter configured to accumulate a phase error between the serial input data and the process clock based on the parallel output data, and output a phase adjusting signal that instructs a phase shift amount for shifting the phase of the process clock in accordance with an accumulated result of the phase error;
an adjusting node configured to receive a test adjusting signal that is used in the second mode; and
a third selector configured to select a first adjusting signal that is the phase adjusting signal in the first mode and is the test adjusting signal in the second mode,
wherein the phase interpolator is configured to shift the phase of the process clock in accordance with the first adjusting signal.

11. The integrated circuit as claimed in claim 10, wherein the digital filter is configured to operate in accordance with the first clock.

12. The integrated circuit as claimed in claim 10, wherein the transmitter and receiver circuit further includes
a first input node configured to receive a third parallel pattern that is used in the first mode;
a second input node configured to receive a test pattern that is used in the second mode; and
a fourth selector configured to select the parallel input data so that the parallel input data is the third parallel pattern in the first mode and is the test pattern in the second mode.

13. The integrated circuit circuit as claimed in claim 12, wherein the transmitter and receiver circuit further includes
a generating circuit coupled to the second input node and configured to generate the test pattern.

14. The integrated circuit as claimed in claim 8, wherein the transmitter and receiver circuit further includes
a judging circuit configured to judge true or false of the parallel output data.

15. The integrated circuit as claimed in claim 14, wherein the judging circuit is configured to operate in accordance with the first clock.

16. A testing method to test a transmitter and receiver circuit that includes a phase interpolator configured to generate a process clock having a phase based on a reference clock, a deserializer, and a serializer, the testing method comprising:
connecting an input of the deserializer configured to convert a serial input data into a parallel output data in accordance with a first clock and output the parallel output data, and an output of the serializer configured to convert a parallel input data into a serial output data in accordance with a second clock and output the serial output data; and
selecting the first clock so that the first clock is the reference clock, and the second clock is the process clock.

17. The testing method as claimed in claim 16, further comprising:
outputting to the phase interpolator a test adjusting signal that instructs a phase shift amount for shifting the phase of the process clock;
outputting a test pattern of the parallel input data; and
judging true or false of the parallel output data.
